(19) United States
(12) Patent Application Publication
(10) Pub. No.: US 2013/0176016 A1
(43) Pub. Date: Jul. 11, 2013

(54) SIGNAL CONVERTING APPARATUS OF POWER METERING SYSTEM, POWER METERING SYSTEM AND METHOD FOR SIGNAL-CONVERTING IN POWER METERING SYSTEM

(71) Applicants: Samsung Electro-Mechanics Co., Ltd., Gyeonggi-do (KR); Korea Electric Power Corporation, Seoul (KR)

(72) Inventor: Shin Jae Kang, Gyeonggi-do (KR)

(73) Assignees: KOREA ELECTRIC POWER CORPORATION, Seoul (KR); SAMSUNG ELECTRO-MECHANICS CO., LTD., Gyeonggi-do (KR)

(21) Appl. No.: 13/678,487

(22) Filed: Nov. 15, 2012

(30) Foreign Application Priority Data
Nov. 18, 2011 (KR) 10-2011-0121039

(51) Int. Cl. H03M 1/00; G01R 21/06; H03M 3/00

(52) U.S. Cl. CPC H03M 1/002; H03M 3/458; G01R 21/06
USPC 324/142; 341/155; 341/143

(57) ABSTRACT

The present invention relates to a signal converting apparatus of a power metering system, a power metering system and a method for signal-converting in a power metering system. In accordance with one embodiment of the present invention, there is proposed to a signal converting apparatus of a power metering system including a frequency shift unit for shifting a frequency(s) of at least one signal of sensed current and voltage signals by a shift frequency(s) so that the current and voltage signals have different frequency bandwidths, a signal coupling unit for coupling the current and voltage signals having different frequency bandwidths into one signal and an analog-digital convert unit for converting an analog signal coupled as said one signal into a digital signal(s). And also, a power metering system including the same and a method for converting a signal of the power metering system are proposed.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2011-0121039, entitled filed Nov. 18, 2011, which is hereby incorporated by reference in its entirety into this application.

### BACKGROUND OF THE INVENTION

1. Field of the Invention

The present invention relates to a signal converting apparatus of a power metering system, a power metering system and a method for signal-converting in a power metering system. More particularly, the present invention relates to a signal converting apparatus of a power metering system, a power metering system and a method for signal-converting in a power metering system to process by combining into one signal by up converting current and voltage signals.

2. Description of the Related Art

In recent, the studies for a smart grid technology through the convergence of information and communication technology and energy technology have been actively realized. In order to implement the smart grid, the usage amount of power is accurately calculated, and an electronic metering technology to convert this into the digital information and a communication technology to transmit the converted digital information are required.

Generally, the electronic metering system is constituted of a signal sensing block, a signal conversion block, a calculation block and a control block; and, in a conventional method, in order to process the voltage and current signals of a single of a 3-phase power signal, each of the analog signals is converted into a digital signal respectively through signal conversion blocks (ADC) of two (voltage and current) or six (3-phase voltages and currents). Accordingly, a large system area and a high current consumption may be caused.

In the conventional method, there are problems that a large area system is required and a high current consumption is generated by being provided with analog-digital converters for each of the single or 3-phase voltage and current signals.

### SUMMARY OF THE INVENTION

The present invention has been invented in order to overcome the above-described problems and it is, therefore, an object of the present invention to process a signal conversion with one analog-digital converter by processing the signal by up converting the frequencies of current and voltage signals and combining these into one signal.

And also, in the conventional method, since the input frequency bandwidth of the analog-digital converter is a low frequency bandwidth (DC˜2KHz), there are problems of the resolution deterioration of ADC due to the DC offset and the 1/f noises and the SNR reduction or the like; and, in accordance with one embodiment of the present invention, it is, therefore, another object of the present invention to process an analog-digital conversion without being affected by the DC offset and the 1/f noises during the analog-digital conversion process or by shifting a frequency into a reduced frequency bandwidth.

In accordance with one aspect of the present invention to achieve the object, there is provided a signal converting apparatus of a power metering system including: a frequency shift unit for shifting a frequency(s) of at least one signal of sensed current and voltage signals by a shift frequency(s) so that the current and voltage signals have different frequency bandwidths; a signal coupling unit for coupling the current and voltage signals having different frequency bandwidths into one signal; and an analog-digital convert unit for converting an analog signal coupled as said one signal into a digital signal(s).

In another example of the present invention, the frequency shift unit may shift each of the sensed current and voltage signals by each of different shift frequencies.

In another example, the current and voltage signals may be 3-phase signals.

And also, in one example, the frequency shift unit may consist of frequency synthesizers to generate frequency-shifted intermediate frequencies by synthesizing frequencies of both signals and each different shift frequency so that the current and voltage signals have different frequency bandwidths; and the signal coupling unit may be a power coupling unit.

And also, in one example, the analog-digital convert unit may include: a sigma-delta converter for converting the analog signal coupled as said one signal into the digital signal; and a digital filter unit for converting the converted digital signal into a desired digital data signal(s) by down-sampling.

At this time, in one example, the digital filter unit may consist of decimation filters, and the decimation filters may convert the converted digital signal into desired N-bit digital data signals by band-pass filtering in a low frequency band and down-sampling.

Also, in one example, the analog-digital convert unit further may include a band pass filter for removing a DC offset and a 1/f noise component in a low frequency band from the converted digital signal in the sigma-delta converter to output the result.

And also, in one example, the signal converting apparatus of a power metering system further may include: frequency down converters for recovering signals corresponding to the current and voltage signals from the digital signal converted in the sigma-delta converter by down-shifting by each shifted frequency, wherein the digital filter unit may convert the current and voltage signals recovered in the frequency down converters into desired digital data signals by down-sampling.

And also, in one example, the signal converting apparatus of a power metering system further may include: frequency down converters for recovering the current and voltage signals from the converted digital data signal(s) by down-shifting by each shifted frequency.

Thereafter, in order to solve the above-described problems, in accordance with the second aspect of the present invention, there is provided a power metering system including: a current and voltage sensing block for sensing current and voltage; a signal converting apparatus of the power metering system according to any one of examples of the above-described one aspect embodiments for converting signals sensed in the sensing block into a digital signal(s); and a digital process block for calculating an amount of power from digital data values outputted in the signal converting apparatus.

And also, in one example, the analog-digital convert unit may include: a sigma-delta converter for converting the analog signal coupled as said one signal into the digital signal; and a digital filter unit for converting the converted digital signal into desired digital data signals by down-sampling, the signal converting apparatus further may include frequency down converters for recovering signals corresponding to the current and voltage signals from the digital signal converted in the sigma-delta converter by down-shifting by each shifted frequency, and the digital filter unit may convert the current and voltage signals recovered in the frequency down converters into desired digital data signals by down-sampling.

And also, in one example, the analog-digital convert unit may include: a sigma-delta converter for converting the analog signal coupled as said one signal into the digital signal; and a digital filter unit for converting the converted digital signal into a desired digital data signal by down-sampling, and the signal converting apparatus further may include frequency down converters for recovering the current and voltage signals from the converted digital data signal by down-shifting by each shifted frequency.

Thereafter, in order to solve the above-described problems, in accordance with the second aspect of the present invention, there is provided a method for signal-converting in a power metering system including: shifting a frequency(s) of at least one signal of sensed current and voltage signals by a shift frequency(s) so that the current and voltage signals have different frequency bandwidths; coupling the current and voltage signals having different frequency bandwidths into one signal; and converting an analog signal coupled as said one signal into a digital signal(s).

In another example of the present invention, in the shifting the frequency each of the sensed current and voltage signals may be shifted by each of different shift frequencies.

In another example, the current and voltage signals may be 3-phase signals.

And also, in one example, said converting an analog signal coupled as said one signal into the digital signal(s) may include: sigma-delta converting the analog signal coupled as said one signal into the digital signal with a sigma-delta modulation method; and converting the digital signal converted in the sigma-delta converting into a digital data signal(s) by down-sampling using a digital filter unit.

In accordance with another example, the digital filter unit may consist of decimation filters, and in the converting the converted digital signal into the digital data signals, a low frequency band-pass filtering and a down-sampling may be performed by using the decimation filters from the converted digital signal to be converted into desired N bit digital data signals.

And also, in accordance with one example, the converting the converted digital signal into the digital data signal(s) further may include removing a DC offset and a 1/f noise component in a low frequency band by using a band pass filter from the converted digital signal in the sigma-delta converting to output the result.

In addition, in accordance with one example, the method for signal-converting in a power metering system further may include: frequency down-converting for recovering signals corresponding to the current and voltage signals from the digital signal converted in the sigma-delta converting by down-shifting by each shifted frequency, wherein the digital filter unit may convert the current and voltage signals recovered in the frequency down-converting into desired digital data signals by down-sampling.

And also, in one example, the method for signal-converting in a power metering system further may include: frequency down-converting for recovering the current and voltage signals from the converted digital data signal by down-shifting by each shifted frequency.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram schematically showing a signal converting apparatus of a power metering system in accordance with one embodiment of the present invention;

FIGS. 2A and 2B are block diagrams schematically showing a signal converting apparatus of a power metering system in accordance with another embodiment of the present invention;

FIG. 3 is a block diagram schematically showing a power metering system including an apparatus for converting a signal in accordance with another embodiment of the present invention;

FIG. 4 is a block diagram schematically showing a signal converting apparatus of a power metering system in accordance with another embodiment of the present invention;

FIGS. 5A and 5B are graphs showing a signal component sensed in a sensing block and a shift frequency in accordance with the embodiments of the present invention;

FIGS. 6A and 6B are graphs showing signal components shifted by a frequency shift unit in accordance with the embodiments of the present invention;

FIG. 7 is a diagram showing signal components coupled by the signal coupling unit in accordance with the embodiment of the present invention;

FIG. 8 is a diagram showing an output frequency spectrum due to a sigma-delta converter in accordance with the embodiments of the present invention;

FIGS. 9A and 9B are diagrams showing signal components processed by frequency down converters and a digital filter unit in accordance with the embodiments of the present invention;

FIG. 10 is a flowchart schematically showing a method for signal-converting in a power metering system in accordance with another embodiment of the present invention;

FIG. 11 is a flowchart schematically showing partial processes of the method for signal-converting in a power metering system in accordance with another embodiment of the present invention;

FIG. 12 is a flowchart schematically showing a method for signal-converting in a power metering system in accordance with another embodiment of the present invention; and

FIG. 13 is a flow chart schematically showing a method for signal-converting in a power metering system in accordance with another embodiment of the present invention.

### DETAILED DESCRIPTION OF THE PREFERABLE EMBODIMENTS

Hereinafter, embodiments of the present invention to achieve the above-described objects will be described with reference to the accompanying drawings. In the present description, like numerals refer to like elements throughout the description of the drawings and parts not relating to the description may be omitted to clearly describe the present invention.

In the present specification, if there is no limitation of “direct” in relations that one element is connected, coupled or arranged to the other elements; they may exist in shapes of “direct connection, couple or arrangement” as well as connection, couple or arrangement by inserting another element therebetween. And also, the terms representing “contact” such as “on”, “above”, “bottom”, “below” or the like are also similar. In case when the element being a reference is inverted or the direction thereof is changed, it will be interpreted that the relative direction concepts corresponding thereto are implicated.

In this specification, the singular form includes the plural form unless the context clearly indicates otherwise. Further, terms “comprises” and/or “comprising” used herein specify the existence of described components, steps, operations, and/or elements, but do not preclude the existence of addition of one or more other components, steps, operations, and/or elements.

Hereinafter, the reference numerals which are not shown in the drawings referred to the detailed description respectively may be the reference numerals shown in the other drawings including the same constructions.

At first, a signal converting apparatus of a power metering system in accordance with a first embodiment of the present invention will be described in detail with reference to the accompanying drawings.

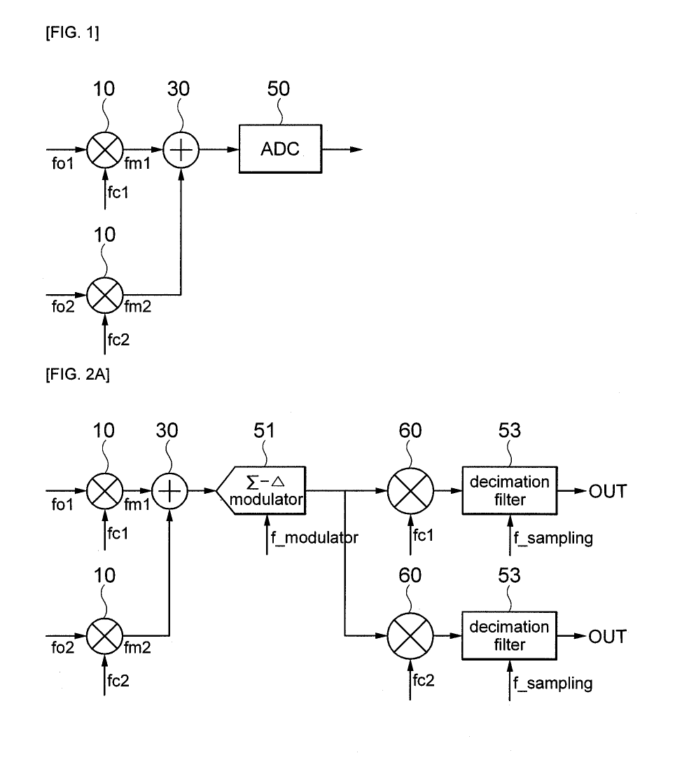

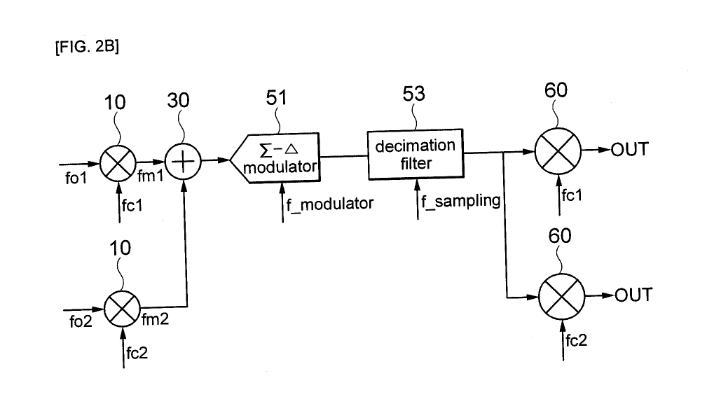

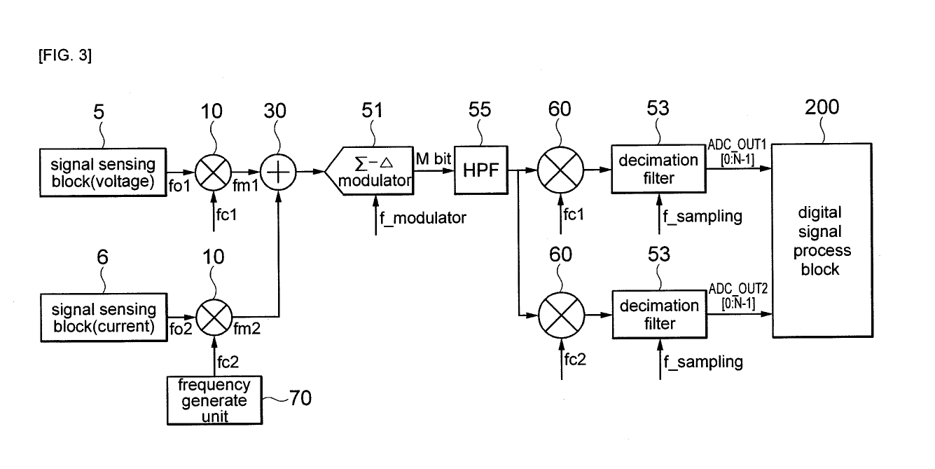

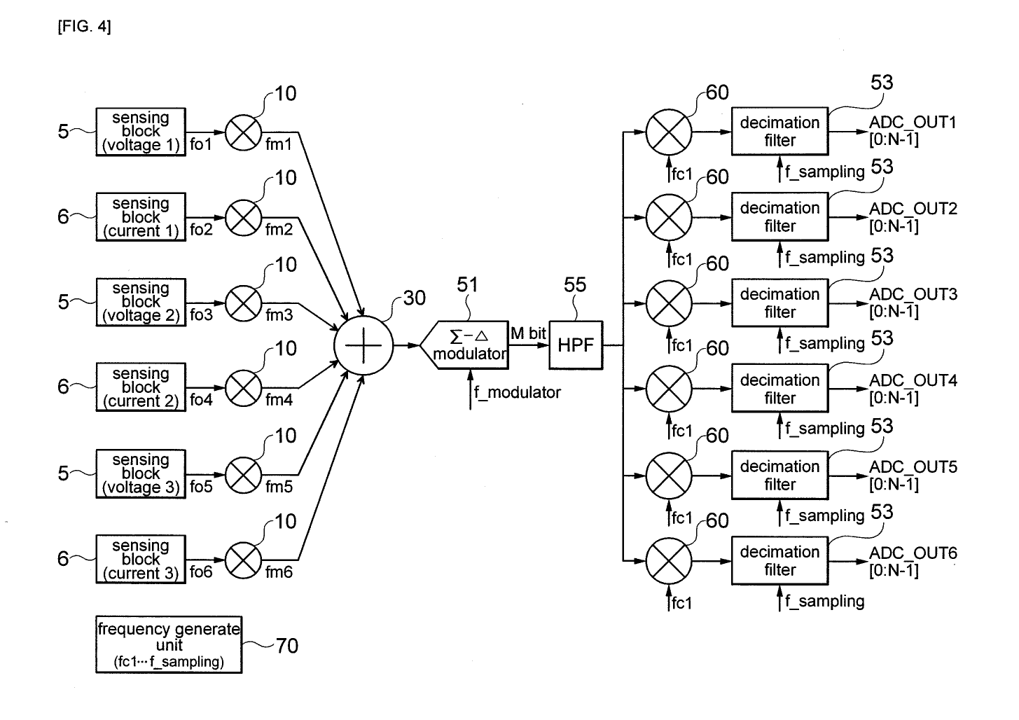

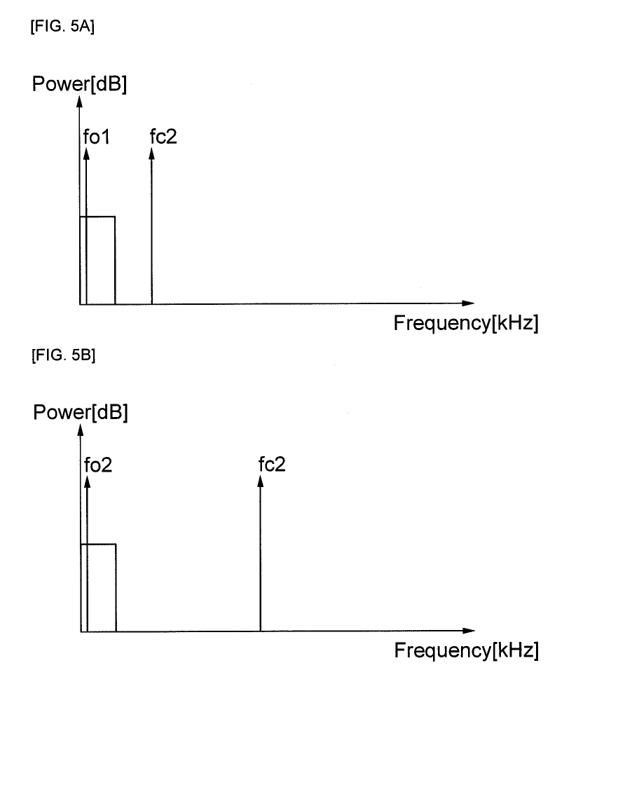

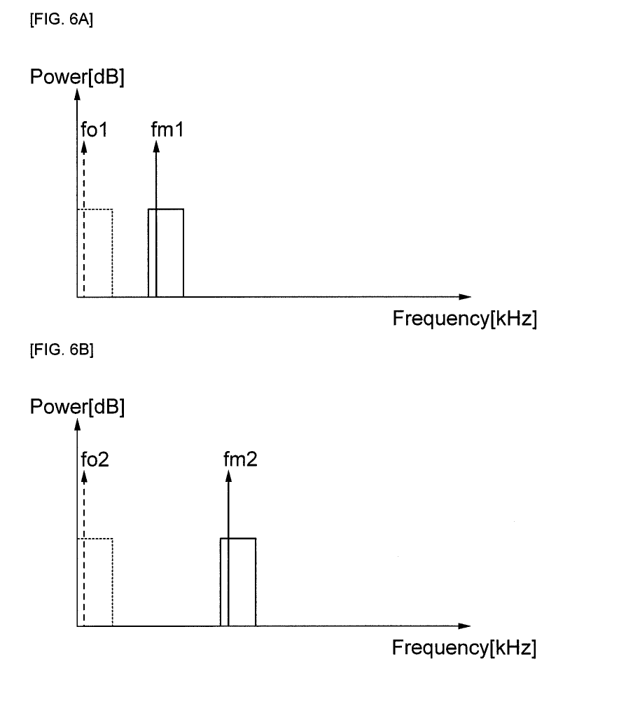

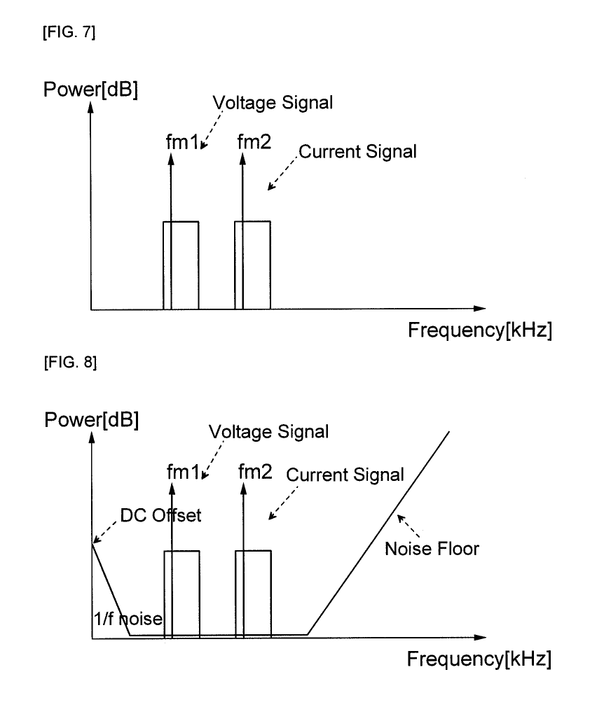

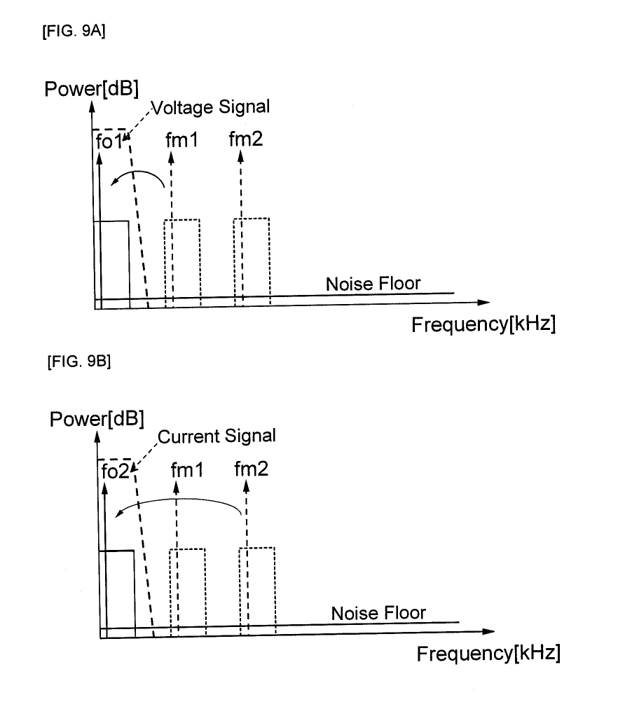

FIG. 1 is a block diagram schematically showing a signal converting apparatus of a power metering system in accordance with one embodiment of the present invention, FIGS. 2a and 2b are block diagrams schematically showing a signal converting apparatus of a power metering system in accordance with another embodiment of the present invention, FIG. 3 is a block diagram schematically showing a power metering system including an apparatus for converting a signal in accordance with another embodiment of the present invention, FIG. 4 is a block diagram schematically showing a signal converting apparatus of a power metering system in accordance with another embodiment of the present invention, FIG. 5 is a graph showing a signal component sensed in a sensing block and a shift frequency in accordance with the embodiments of the present invention, FIG. 6 is a graph showing signal components shifted by a frequency shift unit in accordance with the embodiments of the present invention, FIG. 7 is a diagram showing signal components coupled by the signal coupling unit in accordance with the embodiment of the present invention, FIG. 8 is a diagram showing an output frequency spectrum due to a sigma-delta converter in accordance with the embodiments of the present invention and FIG. 9 is a diagram showing signal components processed by frequency down converters and a digital filter unit in accordance with the embodiments of the present invention;

Referring to FIG. 1, the apparatus for converting the signal of the power metering system in accordance with the first embodiment of the present invention includes a frequency shift unit 10, a signal coupling unit 30 and an analog-digital convert unit 50.

The frequency shift unit 10 shifts the frequency(s) of at least one signal of sensed current and voltage signals by a shift frequency(s) so that the current and voltage signals have different frequency bandwidths. In the frequency shift unit 10, an intermediate frequency(s) is generated by shifting the frequency(s) of at least one signal of sensed current and voltage signals by the shift frequency(s) so that the current and voltage signals have different frequency bandwidths, thereby coupling into one signal without the collision of frequency bandwidths. For example, in case of a single phase system, the current and voltage signals can have different frequency bandwidths by shifting a frequency of any one signal among the current and voltage signals by the shift frequency or the frequencies of both of the current and voltage signals by each of different shift frequencies. At this time, a fundamental frequency signal (˜60 Hz) of the sensed voltage and current signals is deteriorated due to a DC offset and a 1/f noise of signal convert blocks such as a voltage reference block, an ADC or the like to supply a required reference voltage during the signal conversion, whereby the frequency needs to be shifted. At this time, the shift frequency may be a frequency capable of shifting to a frequency bandwidth without being affected by the DC offset and the 1/f noise at a low frequency bandwidth in the analog-digital convert process.

And also, referring to FIG. 1, in one example, the frequency shift unit 10 can shift the sensed current and voltage signals by each of different shift frequencies. According to the present embodiment, by shifting both of the sensed current and voltage signals by each of different shift frequencies, the resolution deterioration of analog-digital converting and SNR reduction or the like due to the DC offset and the 1/f noise at the low frequency bandwidth in the analog-digital convert process can be prevented.

Generally, the signal of power line has the characteristics of intensity of 110V or 220V or a fundamental frequency of 60 Hz; and, at this time, the frequency components generate harmonic components due to the nonlinear characteristics on the paths of a power supply source and power supply line. Generally, since a power meter analyzes until 20^{th} harmonic components, the intermediate frequency between the frequency shifted voltage and current signals can have a shift period, e.g., above 1.2 KHz.

Referring to FIGS. 3 and 5, the current and voltage signals are detected in the current and voltage sensing blocks 5 and 6. At this time, the current and voltage signals can be detected in a shape of voltage signal and the size of a corresponding voltage signal is adjusted by being attenuated with a predetermined ratio in order to meet with an input range for each of the analog-digital conversions. For example, the current signal sensing block 6 can detect the voltage signal through a current transformer CT and a shunt resistor, a Hall sensor or the like. In order not to overlap the frequencies when the current and voltage signals detected in the current and voltage sensing blocks 5 and 6 are coupled to each other, the frequency shift unit 10 shifts the current and voltage signals by different shift frequencies or shifts any one signal among the current and voltage signals by the shift frequencies.

Referring to FIGS. 1 to 3, in one example, the frequency shift unit 10 synthesizes the frequency(s) of at least one signal with the shift frequency(s) to allow the current and voltage signals to have different frequency bandwidths or may be frequency mixers 10 to generate frequency-shifted intermediate frequencys by synthesizing the frequencies of both signals and each of the different shift frequencies, respectively.

Referring to FIGS. 5 and 6, the frequency mixer 10 generate signals corresponding to intermediate frequencies fm1 and fm2 by synthesizing the signals of each of the voltage and current having fundamental frequency component DC˜2 KHz of fo1 and fo2 sensed by each of sensing blocks 5 and 6 of the voltage and current and each of signals having shift frequencies of fc1 and fc2 generated by the frequency generate unit 70. Since the fundamental frequency components of fo1 and fo2 sensed by the sensing block 5 and 6 are in the low frequency bandwidth, in the analog-digital convert process, they can be shifted by the shift frequency not to be affected by the DC offset and 1/f noises in the low frequency bandwidth.

Herein, fm1 is fo1+fc1 and fm2 is fo2+fc2. That is, for example, the voltage and current signal having the fundamental frequency fo is up-converted to the shift frequency of fc1 and fc2 by the frequency mixer, as shown in FIG. 6, the voltage and current conversion signal having an intermediate frequency of fm1 and fm2 may be generated. In FIG. 5, the fo1 is a fundamental frequency of the sensed voltage signal and the fo2 is the fundamental frequency of the sensed current signal. At this time, since the fundamental frequencies are the same frequency of 50 Hz or 60 Hz bandwidth, it needs to be shifted with different frequencies, respectively. In order to differentiate the frequency bandwidths, by synthesizing the shift frequency fc1 for the voltage signal, e.g., the frequency of 1 KHz, and the shift frequency fc2 for the current signal, e.g., the frequency of 2 KHz with each of the fundamental frequencies, as shown in FIG. 6, the frequency is converted into the intermediate frequency fm1 for the voltage signal, e.g., the frequency of 1.06 KHz, and the intermediate frequency fm2 for the current signal, e.g., the frequency of 2.06 KHz. Since the intermediate frequency fm1 for the voltage signal and the intermediate frequency fm2 for the current signal have the different frequency bandwidths, they can be combined into one signal. At this time, although they are explained with the fundamental frequencies fo1 and fo2, the harmonic frequency components can be included except for the fundamental frequencies for the sensed voltage signal and the current signal, such harmonic frequency components are frequency shifted similarly and integrally, and they can be combined into one signal together. And also, the 1 KHz of the shift frequency fc1 and the 2 KHz of the shift frequency fc2 do not limit the scope of the present invention as the examples to help with the understanding of the invention.

Since the analog-digital conversions are performed in each of the frequency bandwidths through the frequency conversion in accordance with the embodiments of the present invention, the interference between different frequencies or different phases can be minimized.

In one example, the current and voltage signals may be a single phase, or as shown in FIG. 4, may be a 3-phase signal. In case of the 3-phase signal, the frequency shift unit 10 shifts the frequencies so as to allow each of the 3-phase voltage and current signals to have different frequency bandwidths. At this time, as shown in FIG. 4, all of the 3-phase voltage and current signals are shifted by each of different shift frequencies, or, not shown in the drawings, by shifting the remaining signals except any one of the 3-phase voltage and current signals by each of different shift frequencies, all of the 3-phase voltage and current signals can have different frequency bandwidths.

In case of the 3-phase signal, since the frequency mixer 10 is required for each phase, for example, 6 numbers of frequency mixers 10, or 7 numbers of frequency mixers 10 for 3-phase 4 wire system are needed. Or except any one of the 3-phase voltage and current signals, in case when the remaining signals are shifted by each of different shift frequencies, only 5 numbers of frequency mixers 10 may be included. Referring to FIG. 4, there is shown for the 3-phase signals, for example, the 6 numbers of frequency mixers 10 are represented.

In FIG. 1, the signal coupling unit 30 couples the current and voltage signals having different frequency bandwidths from each other into one signal.

And also, referring to FIGS. 1 to 3, in one example, the signal coupling unit 30 may be a power combiner 30. In FIG. 1, for example, the frequency shifted voltage signal intermediate frequency fm1 and the frequency shifted current intermediate frequency fm2 are coupled into one signal by the power combiner 30. Referring to FIG. 4, in case for the 3-phase signal, for example, the frequency signals shifted to different frequencies respectively from the frequency mixer 10 may coupled into one signal in the power combiner 30 as having different frequency bandwidths from each other. Referring to FIG. 7, the power combiner 30 generates one signal having the frequency spectrum of the frequency shifted voltage signal intermediate frequency fm1 and the frequency shifted current signal intermediate frequency fm2.

Subsequently, in FIG. 1, the analog-digital convert unit 50 converts the analog signal combined as one signal into the digital signal. The analog-digital convert unit 50 may be formed of an analog-digital converter (ADC) and a filter. The analog-digital converter converts the analog signal combined as one signal into the digital signal, and the converted digital signal passes through the filter in order to remove the noise and to obtain only the necessary frequency bandwidths. In general, the analog-digital converter for the power meter has a resolution above 15 bits.

In general, the signal of the power line has the intensity of 110V or 220V and the frequency characteristics of 60 Hz; and, at this time, the frequency components generate the harmonic components due to the non-linear characteristics on the paths of the power supply source and the power supply lines. In general, since the power meter analyzes to the 20^{th} harmonic components, the analog-digital convert unit 50 outputs as the digital signal of N-bits having a specific sampling frequency fSampling in order to convert the analog signal constituted of the fundamental frequencies and the harmonic components of the frequency shifted current and voltage signals included into the one signal combined in the signal coupling unit 30 into the digital signal. At this time, in order to obtain the high accuracy and high sensitivity, the sigma-delta Σ−Δ method can be employed. The sigma-delta method is formed of a sigma-delta converter 51 for the modulation and a decimation filter(s) 53 for the demodulation.

In accordance with the embodiments of the present invention, for example, since 2 or 6 voltage and current signals can be converted through one analog-digital converter 50 in the single and 3-phase power system, the power consumption and the size of system can be reduced.

And also, one example, the analog-digital convert unit 50 can include the sigma-delta converter 51 and the digital filter unit 53. At this time, the sigma-delta converter 51 converts the analog signal combined as one signal into the digital signal by performing the modulation with the sigma-delta method. The digital filter unit 53 converts the converted digital signal into a desired digital data signal(s) by down-sampling. Referring to FIG. 8, there is shown the output frequency spectrum of the sigma-delta converter 51 for one signal having the frequency shifted voltage signal intermediate frequency fm1 and the frequency shifted current signal intermediate frequency fm2 bandwidths. At this time, the DC offset and the 1/f noises are formed in the low frequency bandwidth, and the high noise frequency spectrum is generated by an intrinsic noise transfer function in the high frequency bandwidth in comparison with the low frequency bandwidth.

At this time, referring to FIGS. 2a, 2b, 3 and 4, in one example, the digital filter unit 53 may consist of the decimation filter(s). The decimation filter(s) 53 can convert into the desired N-bits digital data signal(s) by the low frequency band-pass filtering and down-sampling from the converted digital signal.

Herein, the decimation filter 53 may be formed by including a CIC and Sinc, Half-Band or the like. The decimation filter 53 can remove the noise of the high frequency bandwidth due to a noise transfer function (NTF) of the sigma-delta converter 51 as shown in FIG. 8. And also, the decimation filters 53 generates the output data of the sampling rate to meet with an over sampling ratio (OSR).

Explaining in detail, the analog signal constituted of the fundamental signals and harmonic components of the frequency shifted current and voltage included in the one signal combined in the signal coupling unit 30 is inputted into the sigma-delta converter 51. At this time, the sigma-delta converter 51 can convert into the digital signal of 1 bit by performing the sampling and modulation with the period of the over sampling frequency Fm. The modulation signal of 1 bit over sampled than a practical signal frequency is recovered to the desired sampling frequency fSampling by being demodulated in the decimation filters 53. At this time, the over sampling frequency is several MHz bandwidths and the sampling frequency may have approximately 2 KHZ˜10 KHz bandwidths. Generally, the sampling frequency may have a frequency above 2.4 KHz as two times of the signals of the frequency bandwidth fBW including the fundamental frequency components of 60 Hz and the harmonic frequency components 120 Hz˜1.2 KHz, in the embodiments of the present invention, since the frequency shifted current and voltage signals are included in the one signal in the signal coupling unit, the sampling frequency can be determined considering on the shift frequency.

Referring to FIG. 3, in one example, the analog-digital convert unit 50 can further include the band pass filter 55 to output by removing the DC offset and the 1/f noise components of the low frequency bandwidth from the digital signal converted in the sigma-delta converter 51. At this time, the band pass filter 55 may be a high pass filter (HPF) or a band pass filter (BPF). In FIG. 8, the DC offset and the 1/f noises formed in the low frequency bandwidth may be removed by passing through the a high pass filter (HPF) or the band pass filter (BPF). Although not shown in FIGS. 2a and 2b, a band pass filter 55 may be included after the sigma-delta converter 51.

In accordance with another embodiment, it is available for sampling the signal having the higher SNR, without being affected by the DC offset and the 1/F noises due to the sigma-delta converter 51.

And also, reviewing one example with reference to FIGS. 2a and 2b, the signal converting apparatus of the power meter system can further include frequency down converter(s) 60.

Referring to FIG. 2a, the frequency down converters 60 recover signals corresponding to the current and voltage signals from the digital signal converted in the sigma-delta converter 51 by down-shifting by the shift frequency. At this time, the frequency down converters 60 can recover the current and voltage signals by down-shifting the frequency-shifted current or voltage signals by each shifted frequency. At this time, as not shown in the drawings, on one example, a multiplexer may be inserted in front of the frequency down converters 60 in order to perform a time division processing for each of the corresponding frequencies.

At this time, referring to FIG. 2a, the digital filter unit 53 can convert the current and voltage signals recovered in the frequency down converters 60 into the desired digital data signals by down-sampling. In case the signal of which frequency is not shifted exists, by down-sampling in the digital filter unit 53 directly, the signal may be converted into the desired digital data signal when inputted into the digital filter unit 53 by being divided without passing the process to down-shift by the shift frequency(s) in the frequency down converter(s) 60.

The frequency down converters 60 down-shift the frequencies of the voltage signals and the current signals passing, for example, the high pas filter by each of the shift frequencies fc1 and fc2 to generate the signals by dividing the voltage signal of the frequency fo1 and the current signal of the frequency fo2, respectively. The signal combined as one signal in the power combiner 30 is recovered to the voltage and current signals by each of the frequency down converters 60, respectively. At this time, for example, the decimation filter(s) 53 can convert into the desired N-bit digital data signal(s) with the low frequency band-pass filtering and the down-sampling.

And also, referring to FIG. 2b, in another example, the order of the frequency down converters 60 and the digital filter unit 53 can be processed reversely. That is, the frequency down converters 60 can recover the current and voltage signals from the digital data signal converted in the digital filter unit 53 by down-shifting by the shift frequency. At this time, the frequency down converters 60 can recover the current and voltage signals by down-shifting the frequency-shifted current and voltage signals by the shift frequency. Although not shown, in one example, the multiplexer may be inserted in front of the frequency down converters 60 to perform the time divisional processing for each of the corresponding frequencies.

Referring to FIGS. 9a and 9b, there are shown that the signals corresponding to the voltage and current signals are processed by the frequency down converters 60 and the decimation filters 53, FIG. 9a shows that the signal corresponding to the voltage signals are down shifted by the shift frequency in the frequency down converters 60 and the signals are converted into the desired N-bit digital data signals with the low frequency band pass filtering and the down-sampling in the decimation filters 53, and FIG. 9b shows that the signals corresponding to the current signals are down shifted by the shift frequency in the frequency down converters 60 and the signals are converted into the desired N-bit digital data signals with the low frequency band pass filtering and the down-sampling in the decimation filters 53. The decimation filters 53 can all of the voltage signals fm1 and the current signals fm2 since the pass frequency bandwidths are higher than the frequencies of the voltage signals fm1 and the current signals fm2.

The present embodiments, as shown in FIG. 4, can be applied to the 3-phase power metering system. For example, since 3 pairs of power and current signals are recovered by being shifted into each of the intermediate frequencies IF, the signals can be converted by one analog-digital converter 50.

Since 2 or 6 voltage and current signals are converted through one analog-digital converter 50 in the one-phase and 3-phase power systems, the power consumption and the size of the system can be reduced.

The signal converting apparatus of the power metering system in accordance with the present embodiments may be implemented with an integrated circuit or a system-on-chip.

Thereafter, the power metering system in accordance with the second embodiment of the present invention will be explained in detail with reference to the following drawings. In explain the embodiments of the present invention, the signal converting apparatus of the power metering system in accordance with the above-described first embodiment and FIGS. 1, 2 and 4 to 9 as well as FIG. 3 will be referred; and, accordingly, the repeated description will be omitted.

FIG. 3 is a block diagram schematically showing a power metering system including an apparatus for converting a signal in accordance with another embodiment of the present invention.

Referring to FIG. 3, the power metering system in accordance with the second embodiment of the present invention may be formed by including the current and voltage sensing blocks 5 and 6. The digital signal process block 200, although only shown in FIG. 3, may be included also FIGS. 1, 2a, 2b and 4.

The current and voltage sensing blocks 5 and 6 sense the current and voltage signals. That is, the voltage and the current of the power lines can output the voltage signals corresponding to the sizes thereof by being sensed through each of the sensors. For example, the current and voltage sensing blocks 5 and 6 may be constituted of a current transformer for sensing the part of the current signal and a voltage divider for sensing the part of the voltage signal. The current transformer and the voltage divider attenuate the voltage and the current of the sensed power lines in thousands of 1 and output as the voltage signals of the attenuated sizes.

At this time, the single phase of current and voltage signals can be sensed; and, as shown in FIG. 4, the 3-phase current and voltage signals can be sensed.

Subsequently, the signal converting apparatus of the power metering system converts the signals sensed in the current and voltage sensing blocks 5 and 6 into the digital signal. At this time, the signal converting apparatus of the power metering system may be a signal converting apparatus in accordance with any one of the above-described examples of the first embodiments.

Referring to FIG. 2a, in one example, the signal converting apparatus can further include the frequency down converters 60 to recover signals corresponding to the current and voltage signals by down-shifting from the digital signal converted in the sigma-delta converter 51 by each shifted frequency. At this time, the frequency down converters 60 can recover the current and voltage signals by down-shifting the frequency-shifted current or voltage signals by each shift frequency.

Further, at this time, referring to FIG. 2a, the digital filter unit 53 can convert into the desired digital data signal by down-sampling from the current and voltage signals recovered in the frequency down converters 60.

And also, referring to FIG. 2b, in another example, the signal converting apparatus can further include the frequency down converters 60 to recover the current and voltage signals by down-shifting from the converted digital data signals by the shift frequency. At this time, the frequency down converters 60 can recover the current and voltage signals by down-shifting the frequency shifted current voltage signals by the shift frequency.

The additional explanations will be referred to the above-described first embodiment.

Thereafter, the digital signal process block 200 calculates an amount of power from the digital data values outputted in the signal converting apparatus. The digital signal process block 200 calculates an active power, a reactive power, a power factor or the like required in the power metering system, and may be constituted of an integrator, a multiplexer, a filter or the like by the digital circuits.

The power metering system in accordance with the present embodiments can be implemented with an integrated circuit or a system-on-chip.

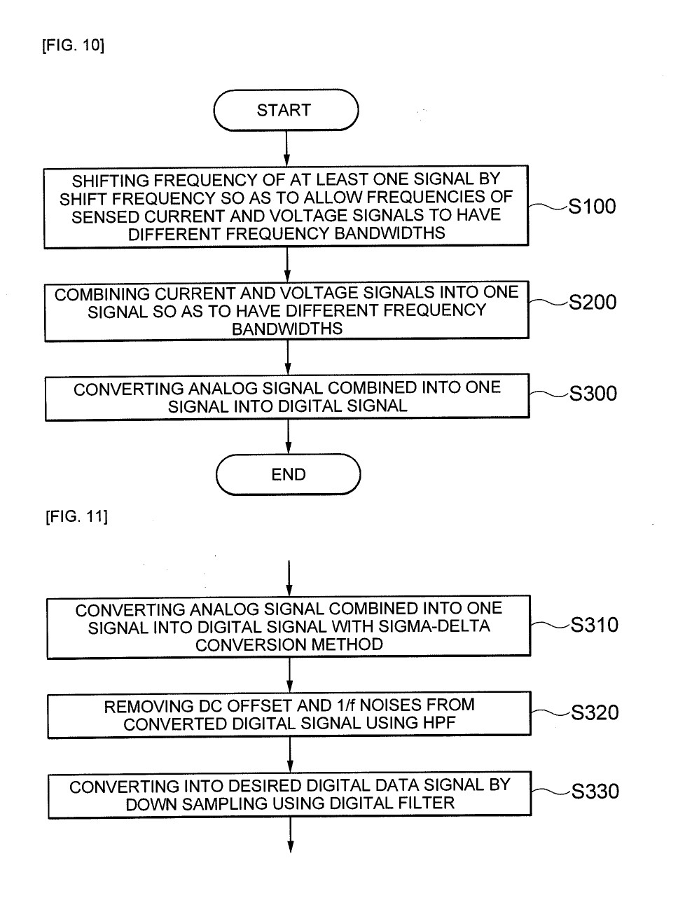

Thereafter, a method for signal-converting in a power metering system in accordance with the third embodiment of the present invention will be described in detail with reference to the drawings. In explain the present embodiments, the signal converting apparatus of the power metering system in accordance with the above-described first embodiment and FIGS. 1 to 9 as well as the following FIGS. 10 to 13 will be referred; and, accordingly, the repeated description may be omitted.

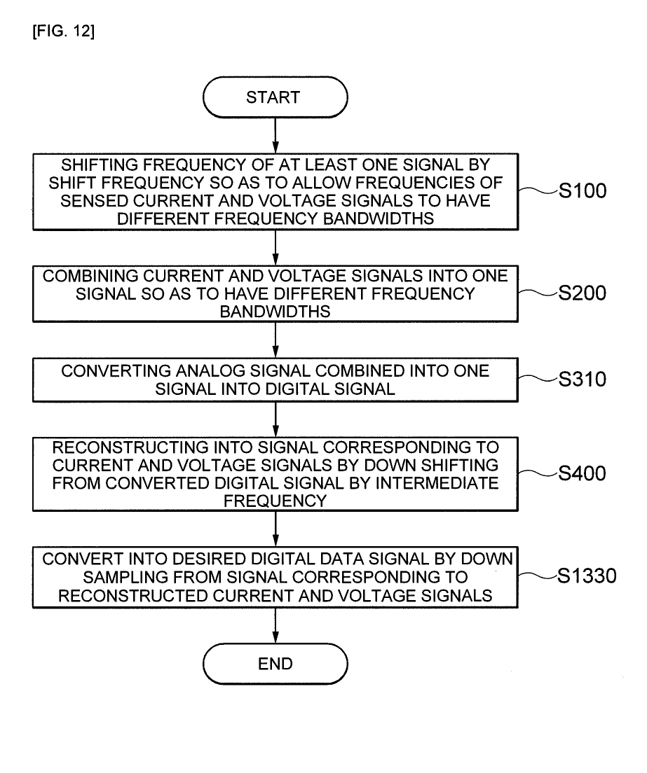

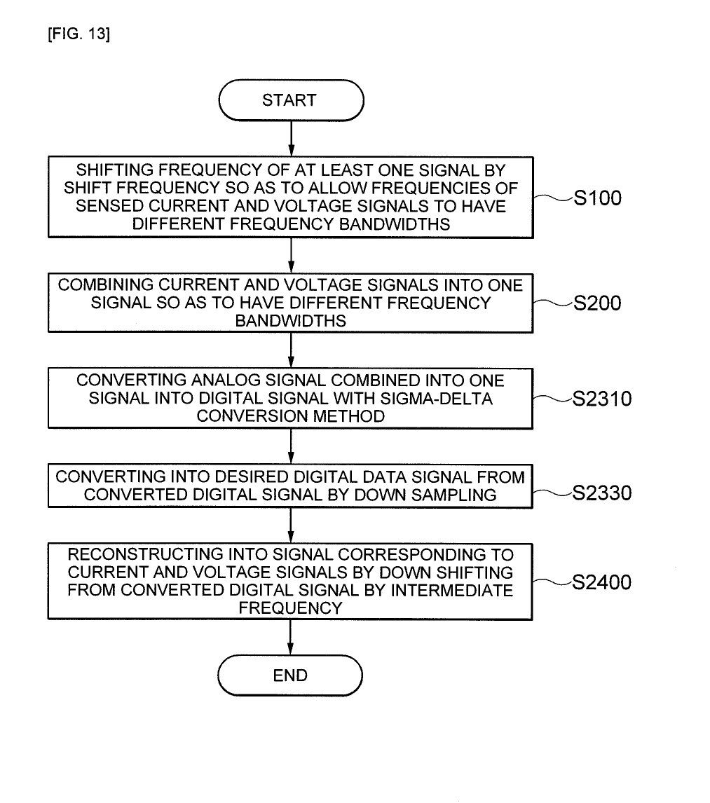

FIG. 10 is a flowchart schematically showing a method for signal-converting in a power metering system in accordance with another embodiment of the present invention, FIG. 11 is a flowchart schematically showing partial processes of the method for signal-converting in a power metering system in accordance with another embodiment of the present invention, FIG. 12 is a flowchart schematically showing a method for signal-converting in a power metering system in accordance with another embodiment of the present invention and FIG. 13 is a flow chart schematically showing a method for signal-converting in a power metering system in accordance with another embodiment of the present invention.

Referring to FIG. 10, the method for converting the signal of the power metering system in accordance with the third embodiment of the present invention is formed by including a step S100 of shifting a frequency, a step S200 of coupling into one signal and an analog-digital conversion step S300. And also, referring to FIGS. 12 and 13, the signal conversion method of the power metering system can further include a frequency down-converting step S400.

In the step S100 of shifting the frequency of FIG. 10, the frequency(s) of at least one signal the sensed current and voltage signals is shifted by the shift frequency(s) so that the current and voltage signals have different frequency bandwidths, respectively. In the step S100 of shifting the frequency(s), by allowing the current and voltage signals to have different frequency bandwidths, they can be combined as one signal without the collision. For example, in case of the single phase system, the frequency of any one signal of the current and voltage signals is shifted by the shift frequency or the frequencies of both of the current and voltage signals are shifted by different shift frequencies, whereby the current and voltage signals can have different frequency bandwidths, respectively.

At this time, on one example, in the step S100 of shifting the frequencies, the sensed current and voltage signals can be shifted by each of different shift frequencies. In accordance with the present embodiments, by shifting all of the sensed current and voltage signals by the shift frequencies, respectively, the resolution deterioration of the analog-digital converting and the SNR reduction or the like due to the DC offset and the 1/f noises in the low frequency bandwidth can be prevented. Also, in one example, the current and voltage signals may be a single phase or may be a 3-phase signal as shown in FIG. 4.

And then, in the step S200 of combining as one signal, the current and voltage signals having different frequency bandwidths are combined into one signal.

Sequentially, in the analog-digital conversion step S300, the analog signal combined into one signal is converted into the digital signal.

And also, in one example, the analog-digital conversion step S300 can include sigma-delta conversion steps S310 and S2310 and steps S330, S1330 and S2330 of converting into the digital data signals. At this time, in the sigma-delta conversion steps S310 and S2310, the analog signal combined into one signal is converted into the digital signal with the sigma-delta conversion method. And also, in the steps S330, S1330 and S2330 of converting into the digital data signals, the signals can be converted into the desired digital data signals by down-sampling from the digital signals converted in the sigma-delta conversion steps S310 and S2310 using the digital filter unit 53.

And also, referring to FIGS. 2a, 2b, 3 and 4, in one example, the digital filter unit 53 may be the decimation filter(s) 53. In the steps S330, S1330 and S2330 of converting into the digital data signals, the signals can be converted into the desired N-bit digital data signals with the low frequency band-pass filtering and the down-sampling using the decimation filters 53 from the converted digital signals.

And also, referring to FIG. 11, reviewing one example, the analog-digital conversion step S300 can further include a step S320 of removing the DC offset and the 1/f noise components of the low frequency bandwidth from the digital signals converted in the sigma-delta conversion step S310 using the band pass filter to output the removed results. At this time, the band pass filter may be the high pass filter (HPF) or the band pass filter (BPF).

In addition, reviewing one example with reference to FIGS. 12 and/or 13, the signal conversion method of the power metering system can further include the frequency down-converting steps S400 and S2400. At first, referring to FIG. 12, in the frequency down-converting step S400, the signals can be recovered into the signals corresponding to the current and voltage signals by down-shifting from the digital signals converted in the sigma-delta conversion step S310 by the shift frequencies. At this time, in the frequency down-converting step S400, the current or the voltage signals can be recovered by down-shifting the frequency shifted current and voltage signals by the shift frequencies. In addition, referring to FIG. 12, at this time, in the step S1330 of converting into the digital data signal, the digital filter unit 53 can convert into the desired digital data signals by down-sampling from the current and voltage signals recovered in the frequency down-converting step S400.

And also, referring to FIG. 13, in another example, 2, in the frequency down-converting step S2400, the current and voltage signals can be recovered by down-shifting from the digital signals converted in the step S2330 of converting into the digital signal by the shift frequencies. At this time, in the frequency down-converting step S2400, the current or the voltage signals can be recovered by down-shifting the frequency shifted current or voltage signals by the shift frequencies.

In accordance with the embodiments of the present invention, by being processed by combining into one signal by up converting the frequencies of the current and voltage signals, two or six voltage and current signals can be processed through one analog-digital converter in the single or 3-phase power system; and, accordingly, the power consumption and the size of the system can be reduced.

And also, in accordance with one embodiment, by processing the analog-digital conversion by shifting the frequencies of the sensed current and voltage signals into different frequency bandwidths, the interference between frequencies different from each other or phases different from each other can be minimized. In addition, in accordance with one embodiment, by processing the analog-digital conversion by shifting the sensed current and voltage signals into the different frequency bandwidths, the sampling of signals having high SNR can be available since the analog-digital conversion process is not affected by the DC offset and the 1/f noises or is reduced to a minimum.

This invention may be embodied in different forms and should not be construed as limited to the embodiments set forth herein. Rather, these embodiments are provided so that this disclosure will be thorough and complete, and will fully convey the scope of the invention to those skilled in the art. As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A signal converting apparatus of a power metering system comprising:
a frequency shift unit for shifting a frequency(s) of at least one signal of sensed current and voltage signals by a shift frequency(s) so that the current and voltage signals have different frequency bandwidths;
a signal coupling unit for coupling the current and voltage signals having different frequency bandwidths into one signal; and
an analog-digital convert unit for converting an analog signal coupled as said one signal into a digital signal(s).

2. The signal converting apparatus of a power metering system according to claim 1, wherein the frequency shift unit shifts each of the sensed current and voltage signals by each of different shift frequencies.

3. The signal converting apparatus of a power metering system according to claim 1, wherein the current and voltage signals are 3-phase signals.

4. The signal converting apparatus of a power metering system according to claim 1, wherein the frequency shift unit consists of frequency synthesizers to generate frequency-shifted intermediate frequencies by synthesizing frequencies of both signals and each different shift frequency so that the current and voltage signals have different frequency bandwidths; and
the signal coupling unit is a power coupling unit.

5. The signal converting apparatus of a power metering system according to claim 1, wherein the analog-digital convert unit includes:
a sigma-delta converter for converting the analog signal coupled as said one signal into the digital signal; and
a digital filter unit for converting the converted digital signal into a desired digital data signal(s) by down-sampling.

6. The signal converting apparatus of a power metering system according to claim 5, wherein the digital filter unit consists of decimation filters, and
the decimation filters convert the converted digital signal into desired N-bit digital data signals by band-pass filtering in a low frequency band and down-sampling.

7. The signal converting apparatus of a power metering system according to claim 5, wherein the analog-digital convert unit further includes a band pass filter for removing a DC offset and a 1/f noise component in a low frequency band from the converted digital signal in the sigma-delta converter to output the result.

8. The signal converting apparatus of a power metering system according to claim 5, further comprising:
frequency down converters for recovering signals corresponding to the current and voltage signals from the digital signal converted in the sigma-delta converter by down-shifting by each shifted frequency,
wherein the digital filter unit converts the current and voltage signals recovered in the frequency down converters into desired digital data signals by down-sampling.

9. The signal converting apparatus of a power metering system according to claim 5, further comprising:
frequency down converters for recovering the current and voltage signals from the converted digital data signal(s) by down-shifting by each shifted frequency.

10. A power metering system comprising:
a current and voltage sensing block for sensing current and voltage;
a signal converting apparatus of the power metering system according to claim 1 for converting signals sensed in the sensing block into a digital signal(s); and
a digital process block for calculating an amount of power from digital data values outputted in the signal converting apparatus.

11. The power metering system according to claim 10, wherein the analog-digital convert unit includes: a sigma-delta converter for converting the analog signal coupled as said one signal into the digital signal; and a digital filter unit for converting the converted digital signal into desired digital data signals by down-sampling,
the signal converting apparatus further includes frequency down converters for recovering signals corresponding to the current and voltage signals from the digital signal converted in the sigma-delta converter by down-shifting by each shifted frequency, and
the digital filter unit for converting the current and voltage signals recovered in the frequency down converters into desired digital data signals by down-sampling.

12. The power metering system according to claim 10, wherein the analog-digital convert unit includes: a sigma-delta converter for converting the analog signal coupled as said one signal into the digital signal; and a digital filter unit for converting the converted digital signal into a desired digital data signal by down-sampling, and
the signal converting apparatus further includes frequency down converters for recovering the current and voltage signals from the converted digital data signal by down-shifting by each shifted frequency.

13. A method for signal-converting in a power metering system comprising:
shifting a frequency(s) of at least one signal of sensed current and voltage signals by a shift frequency(s) so that the current and voltage signals have different frequency bandwidths;
coupling the current and voltage signals having different frequency bandwidths into one signal; and
converting an analog signal coupled as said one signal into a digital signal(s).

14. The method for signal-converting in a power metering system according to claim 13, wherein in the shifting the frequency each of the sensed current and voltage signals is shifted by each of different shift frequencies.

15. The method for signal-converting in a power metering system according to claim 13, wherein the current and voltage signals are 3-phase signals.

16. The method for signal-converting in a power metering system according to claim 13, wherein the converting an analog signal coupled as said one signal into the digital signal(s) includes:
sigma-delta converting the analog signal coupled as said one signal into the digital signal with a sigma-delta modulation method; and
converting the digital signal converted in the sigma-delta converting into a digital data signal(s) by down-sampling using a digital filter unit.

17. The method for signal-converting in a power metering system according to claim 16, wherein the digital filter unit consists of decimation filters, and
in the converting the converted digital signal into the digital data signals, a low frequency band-pass filtering and a down-sampling are performed by using the decimation filters from the converted digital signal to be converted into desired N bit digital data signals.

18. The method for signal-converting in a power metering system according to claim 16, wherein the converting the converted digital signal into the digital data signal(s) further includes removing a DC offset and a 1/f noise component in a low frequency band by using a band pass filter from the converted digital signal in the sigma-delta converting to output the result.

19. The method for signal-converting in a power metering system according to claim 16, further comprising:
frequency down-converting for recovering signals corresponding to the current and voltage signals from the digital signal converted in the sigma-delta converting by down-shifting by each shifted frequency,
wherein the digital filter unit converts the current and voltage signals recovered in the frequency down-converting into desired digital data signals by down-sampling.

20. The method for signal-converting in a power metering system according to claim 16, further comprising:
frequency down-converting for recovering the current and voltage signals from the converted digital data signal by down-shifting by each shifted frequency.
